(19) United States
(12) Patent Application Publication
(10) Pub. No.: US 2026/0133267 A1
(43) Pub. Date: May 14, 2026

(54) SAFETY DEVICE FOR A MAGNETIC RESONANCE IMAGING DEVICE AND METHOD OF USING THE SAFETY DEVICE

(71) Applicant: Friedrich-Alexander-Universität Erlangen-Nürnberg, in Vertretung des Freistaates Bayern, Erlangen (DE)

(72) Inventors: Armin Michael NAGEL, Erlangen (DE); Sebastian BICKELHAUPT, Erlangen (DE); Michael UDER, Erlangen (DE)

(21) Appl. No.: 19/384,004

(22) Filed: Nov. 10, 2025

(30) Foreign Application Priority Data
Nov. 10, 2024 (DE) 10 2024 210 787.5

(51) Int. Cl. G01R 33/28

(52) U.S. Cl. CPC G01R 33/288

(57) ABSTRACT

A safety device for a magnetic resonance imaging device has a connecting portion which is configured to be coupled, in an intended use state, to a patient support and/or guide rail for the patient support of the magnetic resonance imaging device. The safety device further has at least one flatly extending shield portion forming a substantially closed shield surface at least in a line of sight normal to its surface extent, and at least one articulating portion which is arranged between the shield portion and the connecting portion or a further portion and which is configured to enable a rotational adjustment of the shield portion or further portion, preferably about two mutually perpendicular articulation axes.

### CROSS-REFERENCE TO RELATED APPLICATION

This application claims the priority, under 35 U.S.C. § 119, of German Patent Application DE 10 2024 210 787.5, filed Nov. 10, 2024; the prior application is herewith incorporated by reference in its entirety.

### FIELD AND BACKGROUND OF THE INVENTION

The invention relates to a safety device for a magnetic resonance imaging (MRI) device.

MRIs are used for imaging—mostly clinical imaging—, particularly of tissue structures that cannot be visualized using X-ray technology or can only be visualized with considerable effort and, in particular, radiation exposure. For this purpose, magnetic fields are used in an MRI to make use of so-called nuclear magnetic resonance in order to display tissue, etc.

Usually, the coils required to generate the magnetic fields are arranged around a tube—also called a tunnel—in which the object of study (also: patient) is located during the examination. However, the disadvantage of magnetic fields—which are sometimes relatively strong, reaching up to three Tesla or higher in some MRIs—is that their effect also extends outside the tunnel. Metallic parts, particularly those made of ferro-or ferrimagnetic material, can be attracted by magnetic fields, but so can materials with other magnetic properties. Among other things, this can cause the attracted objects to move toward the tunnel, turning them into projectiles, which is undesirable or even dangerous.

This circumstance is usually taken into account through appropriate safety precautions and instructions, one example being that only appropriately qualified personnel are allowed to be present in the vicinity of the MRI. More recently, MRIs have also been used for interventional surgeries in which the MRI is used for imaging during the procedure (e.g., for navigating catheters, endoscopic tools, or the like). As a result, personnel who may not have extensive relevant experience or routine familiarity are often called upon for the patient and thus come near the magnetic fields. On the other hand, emergency situations can also (and possibly additionally) result in safety regulations being overlooked. For example, circumstances may lead a surgeon to forget that they have scissors, a stethoscope, or other metal objects in a pocket of their clothing. What is more, there may be turnover among cleaning staff, meaning that it is not always possible to have a complete overview of adequate training and compliance with safety regulations.

To prevent such situations, an MRI is known from U.S. patent publication No. 2018/0267117 A1, for example, whose tunnel can be closed off by means of a gate-like device.

### SUMMARY OF THE INVENTION

It is the object of the invention to further improve patient safety during imaging using an MRI.

This object is achieved according to the invention by a safety device having the features of the first independent safety device claim that is intended for use with a magnetic resonance imaging device. Furthermore, the object is achieved according to the invention by a second independent safety device claim. Moreover, this object is achieved according to the invention through the use of the safety device with the magnetic resonance imaging device having the features of the independent method claim. Advantageous embodiments and refinements of the invention, some of which are in themselves inventive, are specified in the dependent claims and in the following description.

The protective device according to the invention is designed and intended for use with and for a magnetic resonance imaging device (MRI). For this purpose, the safety device has a connecting portion (or: coupling portion) which is designed and intended to be coupled to a patient table and/or guide rail for the patient table of the MRI in its intended use state. Furthermore, the safety device has at least one flatly extending shield portion (hereinafter also sometimes referred to as “the first shield portion”) which forms a substantially closed shield surface at least in a line of sight normal to its surface extent. In addition, the safety device has at least one articulating portion (hereinafter also sometimes referred to as “the first articulating portion”) which is arranged between the shield portion and the connecting portion or a further portion and which is designed and intended to enable a rotational adjustment of the shield portion or further portion, preferably about two mutually perpendicular articulation axes.

A “substantially closed shield surface” is understood here and below to mean, in particular, that this shield surface forms a continuous surface at least when viewed along the line of sight. In other directions, particularly those oblique to the line of sight, the shield surface may at least optionally have interruptions.

Preferably, the shield portion is made of a material having a sufficiently high breaking strength that (in particular smaller) objects which are attracted from an area in front of the safety device under the effect of a magnetic field of the MRI when the safety device is arranged on the patient table or guide rail can be stopped by the shield portion, in particular without it tearing, breaking, or the like.

The shield portion therefore advantageously serves to stop objects attracted by the magnetic field of the MRI and prevent them from entering an MRI tunnel. By virtue of the articulated articulation of the shield surface, it can be advantageously adjusted as required. The arrangement on the patient table or guide rail thereof makes it possible, in particular, to form a barrier between staff and patient, even during interaction between staff (e.g., a surgeon, specialist staff, or the like) and the patient.

The term “intended use condition” is understood here and below to mean in particular the condition in which the safety device is mounted on the patient table or guide rail thereof (i.e., is coupled thereto).

According to an alternative embodiment, the safety device according to the invention has, instead of the connecting portion, a frame portion which supports the at least one shield portion (already described above). The frame portion supports the shield portion in such a way that the shield portion, in a setup (of the safety device) as specified, at least partially covers the patient table of the magnetic resonance imaging device and/or a space occupied by a person lying on the patient table relative to a horizontal line of sight when the magnetic resonance imaging device is being used in an intended manner. Therefore, in this embodiment as well, the shield portion preferably covers the patient table or the space above it in which the patient is located during normal use, at least partially, thus advantageously also forming the barrier described above. The safety device therefore also has the at least one flatly extending (above-described) shield portion and the at least one articulating portion which is arranged between the shield portion and the frame portion or the further portion and which is configured and intended to enable a rotational adjustment of the shield portion or further portion, preferably about the two mutually perpendicular articulation axes.

Optionally, the frame portion is designed with a height that allows the arrangement of the shield portion described above, for example, the height of conventional patient tables. Alternatively, the frame portion can also have a height-adjustable option, e.g., a type of telescope, in order to be able to adjust the height of the shield portion relative to the patient table.

Preferably, in the intended use state, an articulation axis of the articulating portion is aligned parallel to a tunnel axis of the tunnel of the MRI or perpendicular thereto. As a result, the shield portion can be tilted toward the patient, in particular above the patient, or in the case of vertical alignment, in particular when the patient table is moved into the tunnel, it can be pivoted in front of the tunnel so that the tunnel is covered at least parallel to the tunnel axis (and at least partially as a function of the size of the shield portion).

In the event that the shield portion is adjustable about two articulation axes aligned perpendicular to one another, both adjustments of the shield portion described above can be advantageously carried out.

According to one expedient embodiment, the connecting portion has, for example, a type of sliding block as a connecting element to the guide rail which can be inserted into a T-slide-like guide groove of the guide rail. Preferably, this sliding block is also spring-loaded or coupled to a clamping device, so that a position of the safety device along the guide rail can be selected but also fixed—in particular by means of a spring-force—or mechanically induced clamping. For mounting on the patient table, the connecting portion has, for example, a clamping device that is adapted to an edge contour of the patient table. This clamping device is designed to be comparable to a clamp (e.g., a toggle clamp) or a roof rack for a motor vehicle. In particular, the clamping device offers the advantage of enabling reversible coupling of the safety device to the MRI. Preferably, the connecting portion is designed for reversible coupling to the patient table or guide rail. The connecting portion can, however, optionally also be designed for permanent attachment to the patient table or guide rail and has for this purpose a type of connecting foot that makes the flattest and thus most stable support possible and is used for irreversible connection, e.g., by means of screws, optionally also by welding, gluing, or the like.

According to one expedient embodiment, the articulating portion has a ball joint. This ball joint is preferably connected between the shield portion and the connecting portion or frame portion. A ball joint advantageously has almost free rotational mobility, so that the shield portion can be pivoted in multiple spatial directions. In order to enable the performed adjustment (alignment) of the shield portion, the ball joint optionally has a clamping screw or the like. This enables unintentional movement of the shield portion to be prevented in a simple and effective manner.

According to an advantageous refinement, the articulating portion has two support rods, each of which is connected to the connecting portion or frame portion and shield portion by means of a ball joint. By virtue of the two connection points, the safety device advantageously provides for comparatively stable mounting of the shield portion. This can prevent the shield portion from moving in any unintended manner, e.g., from being folded over or the like, or at least it can reduce the risk of this happening. Furthermore, the two support rods, particularly if they are both connected to a lower edge of the shield portion, for example, enable the height of the shield portion to be adjusted (when in the intended use state), in particular at least in the range of the length of the support rods. Preferably, the two support rods are aligned parallel to one another when the shield portion is in a home position in which it is aligned vertically and parallel to the tunnel axis.

According to one expedient embodiment, the shield portion has a membranous body with a closed surface. The term “membranous body” is understood here and in the following to refer in particular to a body with a planar extent and a thickness which is small (particularly many times smaller, e.g., at least ten times smaller) in comparison thereto—i.e., compared to at least the length and/or width. In addition, the surface of the membranous body can also be curved, bent, or the like, and does not have to be strictly two-dimensional. Preferably, the membranous body is made of a plastic, preferably a fiber-reinforced plastic, or of a plastic textile (woven fabric, knitted fabric, or the like). The plastic construction enables a lightweight and/or three-dimensionally shaped structure to be implemented simply and cost-effectively.

Advantageously, the membranous body has an edge bent away from the tunnel on at least one edge facing toward the tunnel of the MRI in the intended use state. In the case of the ball joint, this edge can therefore be (particularly in the home position) at least the (particularly vertically aligned) edge pointing toward the tunnel. Alternatively or optionally, this may be the edge pointing upward in the home position (particularly in the case of an approximately rectangular shield portion, the edge that is aligned parallel to the patient table or guide rail thereof in the home position). Optionally, the (respective) edge is bent by at least 90 degrees, preferably by 100 degrees or up to 180 degrees, with a bending radius of 1 to 4 cm, for example. This results in a roughly J-shaped contour or “pocket” when viewed in cross section in which at least small objects, such as paper clips or the like, can be caught.

According to another expedient refinement, the membranous body has, particularly on its underside, i.e., in the region of the downward-facing edge, a marginal recess or an internal opening which serves the purpose of guiding a hose or other conduit into the tunnel during its intended use. A “marginal recess” is understood to mean, in particular, a lateral incision, e.g., with a U-shape, in the membranous body, which is thus open to the environment at the edge. An “internal opening,” on the other hand, is understood as an aperture through the body that is enclosed in a ring-like manner by the membranous body. Through this recess or internal opening, conduits (e.g., a ventilation tube, a tube for intravenous medication, anesthesia, or the like) can be fed into the tunnel while the tunnel is more or less covered by the shield portion on the outside.

As an alternative to the membranous body, the shield portion is formed by a net-like structure. This preferably has comparable properties to the membranous body described above, apart from the mesh openings, which are expediently selected so as to be so small that even small objects cannot pass through or can only do so with negligible probability. The (net) openings have a diameter or edge length of 2-10, preferably only 2-5 mm.

According to another alternative design to the membrane-like body, the shield portion has a ring-shaped frame on which a multitude of cables (or also: cords) are stretched to form a quasi-closed surface. The term “quasi-closed” is understood here and below in particular to mean that the shield surface—as described above—is closed along the said line of sight normal to the surface extent of the shield surface but has interruptions obliquely thereto (in particular from a perspective rotated around one of the cables), namely the areas between the individual cables.

According to a preferred refinement, the abovementioned cables are arranged parallel to one another and in (at least) two layers in the thickness direction and offset transversely to their longitudinal extent. The cables are expediently stretched in two “layers” one above the other in the direction of thickness, with the two layers being offset transversely to each other by an amount, depending on the cable width, of slightly less than one cable width, for example. This results in a closed surface when viewed along the normal direction. This is suitable for detaining larger objects such as pens, scissors, and stethoscopes, or at least slowing them down substantially—the probability of an elongated object striking the cables at an ideal angle and gliding through smoothly being rather low. In addition, the cables also offer the possibility for a person to reach through and/or for cables to be passed through.

According to one expedient embodiment, the safety device has the further portion. This further portion is embodied as a further shield portion and is movably coupled to the (first, i.e., further) shield portion by means of the (above-described first) articulating portion or of a further articulating portion.

According to an exemplary refinement, the first shield portion is connected to the connecting portion or frame portion by means of the first articulating portion, which in particular is a hinge with a hinge axis (or: articulation axis) that is aligned parallel to the tunnel axis in the intended use state. The first shield portion is also connected to the further (or: “second”) shield portion by means of the further (“second”) articulating portion, which has an articulation with at least one pivot axis (articulation axis) which, in the intended use state, lies in a plane perpendicular to the tunnel axis. In this case, in the intended use state, the first shield portion can be tilted toward (or away from) the patient, and the second shield portion can be pivoted relative to the first shield portion. This means that the second shield portion can be used, for example, to conceal the tunnel entrance from a line of sight along the tunnel axis.

In the embodiments described above, the first shield portion—in the intended use state and at least when the first articulating portion is in certain orientations—forms a partition between personnel (e.g., surgeon) and patient, particularly when the surgeon is performing an intervention on the patient.

According to an expedient embodiment, the safety device has a telescopic portion which is connected between the (first) shield portion and the connecting portion (or frame portion). This telescopic portion has a telescopic function parallel to the tunnel axis in the intended use state. The telescopic portion is thus designed and intended to hold the first shield portion displaceably relative to the connecting portion (or frame portion). As a result, the first shield portion, particularly if an object attracted by the magnetic field of the MRI is arranged thereon, can be removed from the MRI, preferably to such an extent that the magnetic field is weakened enough that the corresponding object is no longer attracted and can thus be removed. Optionally, the ic portion can also be combined with the articulating portion, for example by designing the support rods described above as telescopic rods.

The frame portion is, for example, a substructure such as a frame or similar with extended foot parts to enable the most stable setup possible. Preferably, rollers (preferably lockable ones) are arranged on the frame portion, specifically on the foot parts, enabling the entire safety device to be easily moved.

According to the invention, the safety device described above is used with the magnetic resonance imaging (MRI) device. For this purpose, the safety device is attached to the patient table and/or guide rail for the patient table by means of the connecting portion.

The conjunction “and/or” is to be understood here and in the following specifically such that the features linked by this conjunction can be formed both jointly and as alternatives to one another. The use according to the invention therefore has the same features and resulting advantages as the safety device described above.

Other features which are considered as characteristic for the invention are set forth in the appended claims.

Although the invention is illustrated and described herein as embodied in a safety device for a magnetic resonance imaging device, it is nevertheless not intended to be limited to the details shown, since various modifications and structural changes may be made therein without departing from the spirit of the invention and within the scope and range of equivalents of the claims.

The construction and method of operation of the invention, however, together with additional objects and advantages thereof will be best understood from the following description of specific embodiments when read in connection with the accompanying drawings.

### BRIEF DESCRIPTION OF THE FIGURES

FIG. 1 is a schematic view of an MRI in a frontal view into an MRI tunnel;

FIG. 2 is a side view of the MRI;

FIG. 3 is a top view of a part of a safety device for the MRI;

FIG. 4 is a schematic view of an alternative exemplary embodiment of the safety device in a detailed view of FIG. 2;

FIG. 5 is a schematic view of another exemplary embodiment of the safety device in a view according to FIG. 4;

FIG. 6 is a schematic view of another exemplary embodiment of the safety device in a view according to FIG. 4;

FIG. 7 is a detailed cut-out of the safety device according to FIG. 6 in a view according to FIG. 3;

FIG. 8 is a schematic of another exemplary embodiment of the safety device in a view according to FIG. 4;

FIG. 9 is a schematic of the safety device according to FIG. 8 in a view according to FIG. 1; and

FIG. 10 is a schematic of an alternative exemplary embodiment of the safety device in a view according to FIG. 1.

Analogous parts are always provided with the same reference symbols in all figures.

### DETAILED DESCRIPTION OF THE INVENTION

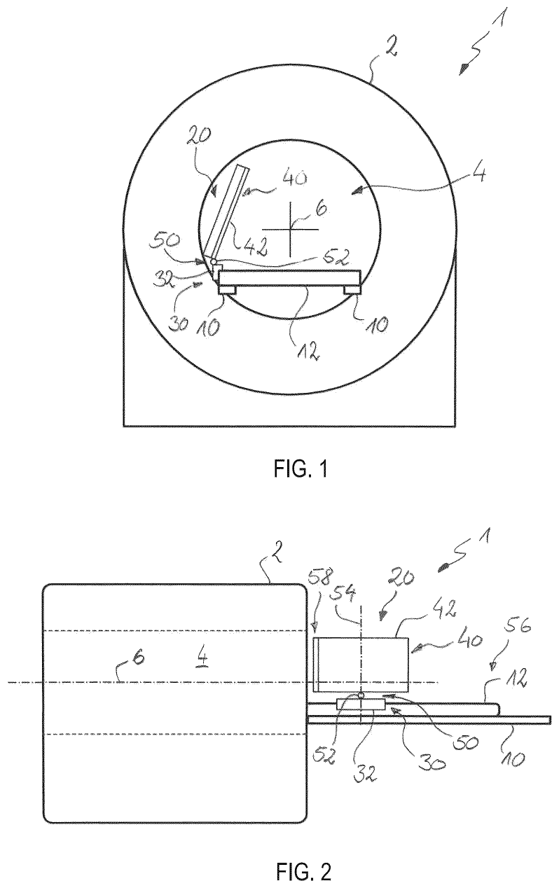

Referring now to the figures of the drawings in detail and first, particularly to FIG. 1 thereof, there is shown a schematic diagram of a magnetic resonance imaging device, abbreviated as “MRI 1.” The MRI 1 has a housing 2, which in the illustrated exemplary embodiment surrounds a frame and a number of magnetic coils and shields them from access. The magnetic coils are arranged and the housing 2 designed accordingly such that an examination tunnel, abbreviated as the tunnel 4, is formed which extends along a tunnel axis 6. In order to image an object, in particular a patient, for examination, the object is pushed into the tunnel 4 and thus into the magnetic field formed by the magnetic coils. For this purpose, the MRI 1 has guide rails 10 and a patient table 12 movably mounted thereon (and can be moved automatically by means of a drive, which is not shown in further detail).

During operation of the MRI 1, field lines of the magnetic field extend not only within the tunnel 4, but also outside it. Also depending on the field strength used, this can result in magnetic or magnetizable objects outside the MRI 1 being attracted by the magnetic field and possibly drawn into the tunnel 4. This poses a danger to bystanders and/or to the person being examined. In order to reduce such a hazard potential, a safety device 20 is used which is described in greater detail in the following.

The safety device 20 is configured and intended to be reversibly attached to the patient table 12. The safety device 20 has a connecting portion 30. The connecting portion 30 is designed for clamping connection to the patient table 12, comparable to a roof rack of a motor vehicle. For this purpose, the connecting portion 30 has a support foot 32 which (not shown in detail) engages around a side edge of the patient table 12 in a clamp-like manner or with two clamping jaws when coupled to the patient table 12. One of the clamping jaws can be adjusted toward or away from the other by means of a clamping screw, enabling the clamping force on the patient table 12 to be increased or decreased. Alternatively, one of the clamping jaws can also engage in a groove in the patient table. Alternatively, the support foot 32 can also be screwed to the patient table 12.

Moreover, the safety device 20 also has at least one shield portion 40. According to the exemplary embodiments of FIGS. 1 to 5, 8, and 9, this shield portion 40 has a flatly extending membranous body 42 which is at least largely rectangular in shape. In these exemplary embodiments, the body 42 is formed on a fiber-reinforced plastic plate.

The safety device 20 has an articulating portion 50. This forms a connecting link between the connecting portion 30 and the shield portion 40. In the exemplary embodiment according to FIGS. 1 and 2, the articulating portion 50 has (only) one ball joint 52. Due to the ball joint 52, the shield portion 40, specifically the body 42, is comparatively free relative to the connecting portion 30 and, in the intended use state on the MRI 1 (i.e., attached to the patient table 12; see FIGS. 1 and 2), can thus be adjusted relative to the patient table 12. In particular, the body 42 can be tilted toward the patient table 12 (or, conversely, set upright or tilted away from it) about an axis that runs parallel to the tunnel axis 6.

This makes it possible for staff who need to interact with the patient before or during the examination to stand next to the patient table 12 and in front of the shield portion 40 as if in front of a paravent or folding screen. The body 42 protects the patient from objects attracted by the magnetic field, such as those being carried by the staff or the like.

In addition, the body 42 can also be pivoted about a vertical axis 54 which is perpendicular to the tunnel axis 6. As a result, the body 42 can at least partially cover the opening of the tunnel 4 (depending on the “length” of the body 42 along the tunnel axis 6, at least when the body 42 is in a home position—parallel to a vertical and parallel to the tunnel axis 6). The latter can be used, for example, if the safety device 20 is mounted in the area of the foot end 56 (the right end in FIG. 2) of the patient table 12 and/or the patient is pushed completely into the tunnel 4 in order to quasi close off the tunnel 4. Objects that are attracted at least roughly along the tunnel axis 6 can thus be prevented from penetrating into the tunnel 4. Optionally, for the latter, a safety device 20 is arranged on both sides of the patient table 12 whose body 42 can then be closed in front of the tunnel 4 in a manner comparable to a double-leaf door.

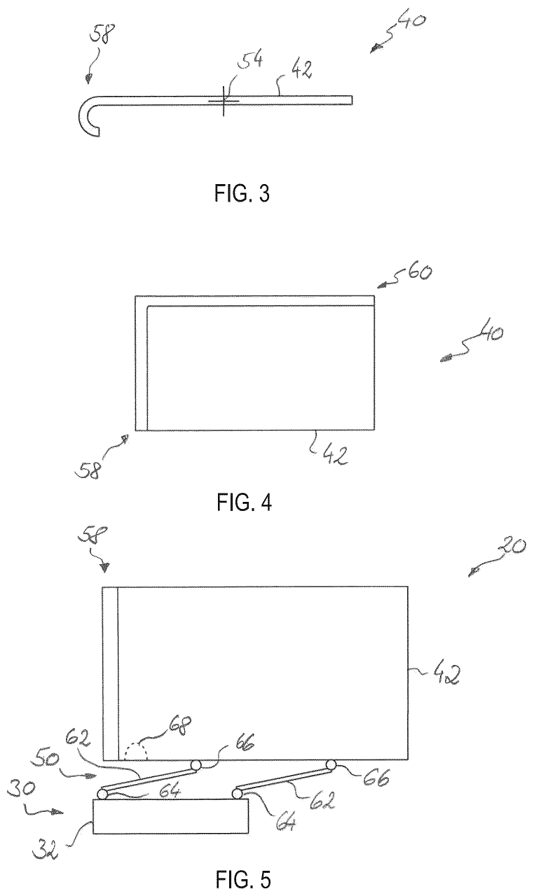

In order to prevent an object that is attracted by the magnetic field and strikes the body 42 from sliding along the same in the direction of the MRT 1 and slipping off the end of the body 42 and still striking the MRT 1 or even getting into the tunnel 4, the body 42 has a bent edge 58 (see FIG. 3) on an edge that faces toward the MRT 1 in the intended use state (see FIG. 2, for example). In the present exemplary embodiment, the edge 58 is bent by 180 degrees with a bending radius of 3 cm. This creates a kind of pocket in which at least smaller objects can be caught.

FIG. 4 shows here an alternative exemplary embodiment of the body 42. Here, not only is the edge 58 bent, as shown in FIG. 3, but also the edge 60 opposite the articulating portion 50. Optionally, this can be bent in the same way as the edge 58, but it can also be bent less, e.g., by only 90 degrees.

FIG. 5 shows another exemplary embodiment of the safety device 20. Here, the articulating portion 50 has two rods 62 (support rods), each of which is articulated to the connecting portion 30 by means of a ball joint 64 and to the shield portion 40 by means of a further ball joint 66. Among other things, these rods 62 make a certain height adjustment of the shield portion 40 possible relative to the patient table 12.

FIG. 5 shows an example of an optional edge-side recess 68 in the body 42. This serves the purpose of guiding cables, hoses, or the like “through” the safety device 20 into the tunnel 4, in particular when the tunnel 4 is covered by the body 42.

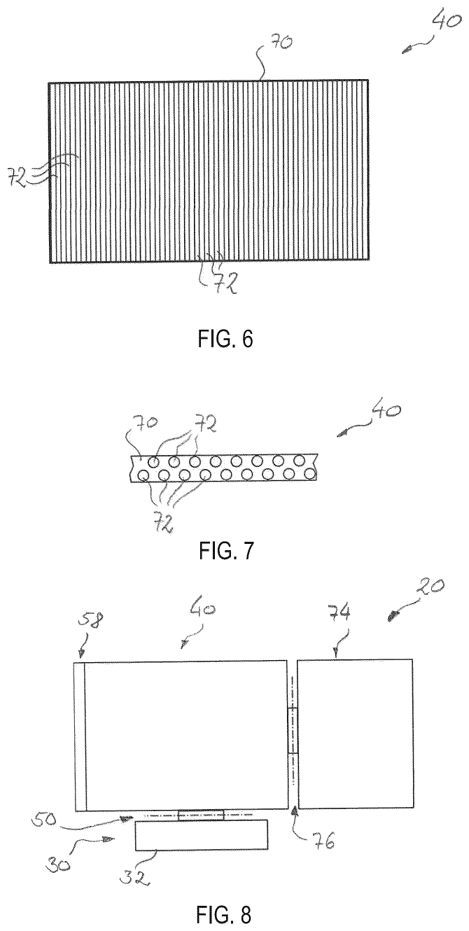

Another exemplary embodiment of the safety device 20 is shown in FIGS. 6 and 7. Instead of the membranous body 42, this has a rectangular frame 70 in which cables 72 are stretched in two planes or layers lying one above the other in the direction of thickness (see FIG. 7). The cables 72 of the two levels are offset transversely to their longitudinal extent, meaning that they are “spaced apart.” This results in a closed surface when viewed along the thickness direction. For example, the two planes are arranged at the same distance from one another but in particular at a smaller distance than the cables 72 of the same plane. This means that two adjacent cables 72 of different levels are arranged closer to each other than two adjacent cables 72 of the same level. The cables 72 make it possible, on the one hand, for personnel to reach between the cables 72, but, on the other hand, they also enable elongated objects, or at least those whose diameter is greater than the distance between two cables 72, to be stopped by the cables 72, thus preventing them from penetrating through to the patient and/or into the tunnel 4.

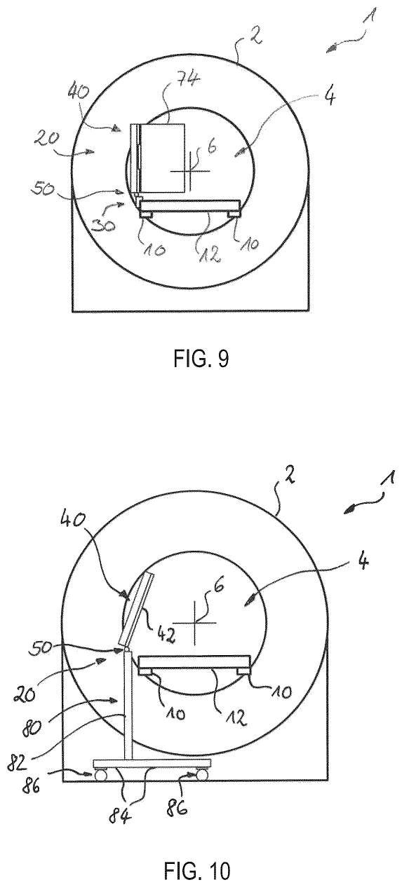

FIGS. 8 and 9 illustrate yet another exemplary embodiment of the safety device 20. In this case, it comprises a further shield portion 74 and an articulating portion 76. The further shield portion 74 has a body which—optionally except for a bent edge—corresponds to the design of the body 42 or also to the variant with the cables 72 between the shield portion 40. In this case, the (“first”) articulating portion 50 has only one articulation axis, which is aligned parallel to the tunnel axis 6 in the intended use state. The further articulating portion 76 is arranged between the shield portion 40 and the further shield portion 74 and has only one articulation axis, which in the intended use state lies in a radial plane to the tunnel axis 4. As a result, the further shield portion 74 is hinged to the first shield portion 40 like a door leaf and can be used, for example, to cover the tunnel 4 from the “front,” at least up to halfway. By using two safety devices 20, one on each side of the patient table 12, the tunnel 4 can thus be almost completely closed off.

FIG. 10 shows a schematic of an alternative exemplary embodiment of the safety device 20. In this case, the safety device 20 is embodied as a device separate from the MRI 1, specifically from the patient table 12. For this purpose, the safety device 20 has a frame portion 80 instead of the connecting portion 30. The frame portion 80 has a substructure 82, made of tubes, for example, preferably of fiber-reinforced plastic tubes or the like, which is designed to be movable in space by means of laterally extended foot parts 84 and rollers 86 arranged thereon. The shield portion 40 is articulated and fastened to the frame portion 80 by means of the articulating portion 50 analogously to the above description. Otherwise, the exemplary embodiments described above, particularly of the shield portion 20 (where applicable, also of the shield portion 74) and of the articulating portion 50 (where applicable, of the articulating portion 76) are equally applicable to this exemplary embodiment. This makes an especially high degree of mobility of the safety device 20 possible. The frame portion 80 also has a height which corresponds to the height of the patient table or which results in an arrangement of the shield portion 40 that allows for at least partial coverage (screening) of the space occupied by the patient for the staff (see FIG. 10).

Optionally, it is also conceivable for the shield portion 20 to be connected to the frame portion 80 by means of the connecting portion 30 (comparable to the patient table 12).

The subject of the invention is not limited to the embodiment described above. Rather, other embodiments of the invention may be derived from the description above by a person skilled in the art. In particular, the individual features of the invention and their design variants described with reference to the various exemplary embodiments can also be combined with one another in other ways.

The following is a summary list of reference numerals and the corresponding structure used in the above description of the invention:
1 MRI
2 housing
4 tunnel
6 tunnel axis
10 guide rail
12 patient table
20 safety device
30 connecting portion
32 support foot
40 shield portion
42 body
50 articulating portion
52 ball joint
54 vertical axis
56 foot end
58 edge
60 edge
62 rod
64 ball joint
66 ball joint
68 recess
70 frame
72 cable
74 shield portion
76 articulating portion
80 frame portion
82 substructure
84 foot part
86 roller

1. A safety device for a magnetic resonance imaging device, the safety device comprising:
a connecting portion configured for coupling to a patient table and/or a guide rail for the patient table of the magnetic resonance imaging device in an intended use state;
at least one flatly extending shield portion forming a substantially closed shield surface at least in a line of sight normal to its surface extent; and
at least one articulating portion disposed between said at least one flatly extending shield portion and said connecting portion or a further portion and configured to enable a rotational adjustment of said at least one flatly extending shield portion or said further portion.

2. The safety device according to claim 1, wherein said at least one articulating portion has a ball joint.

3. The safety device according to claim 2, wherein said at least one articulating portion has two support rods which are each connected to said connecting portion and said at least one flatly extending shield portion by means of said ball joint.

4. The safety device according to claim 1, wherein said at least one flatly extending shield portion has a membranous body with a closed surface.

5. The safety device according to claim 4, wherein said membranous body has, on at least one edge facing toward a tunnel of the magnetic resonance imaging device in the intended use state, an edge which is bent away from the tunnel.

6. The safety device according to claim 4, wherein said membranous body has a marginal recess or an internal opening formed therein which enables a hose or other conduit means to be fed into the tunnel during intended use.

7. The safety device according to claim 1, wherein said at least one flatly extending shield portion has a ring-shaped frame on which a plurality of cables are stretched to form a quasi-closed surface.

8. The safety device according to claim 7, wherein said cables are arranged parallel to one another and in two layers in a thickness direction and offset transversely to their longitudinal extent.

9. The safety device according to claim 8, wherein said further portion is embodied as a further shield portion and is movably coupled to said at least one flatly extending shield portion by means of said at least one articulating portion or a further articulating portion.

10. The safety device according to claim 9, wherein:
said at least one flatly extending shield portion is coupled to said connecting portion by means of said at least one articulating portion, which has a hinge with a hinge axis aligned parallel to the tunnel axis in the intended use state; and
said at least one flatly extending shield portion is coupled to said further shield portion by means of said further articulating portion, which has an articulation with at least one pivot axis which, in the intended use state, lies in a plane perpendicular to the tunnel axis.

11. The safety device according to claim 1, further comprising a telescopic portion which is connected between said at least one flatly extending shield portion and said connecting portion and said telescopic portion, in the intended use state, has a telescopic function oriented parallel to the tunnel axis.

12. A method of modifying a magnetic resonance imaging device having a patient table and a guide rail, which comprises the steps of:
providing the safety device according to claim 1; and
fastening the safety device to the patient table and/or the guide rail for the patient table by means of the connecting portion.

13. A safety device for a magnetic resonance imaging device, the safety device comprising:
at least one flatly extending shield portion forming a substantially closed shield surface at least in a line of sight normal to its surface extent;
a frame portion supporting said at least one flatly extending shield portion such that said at least one flatly extending shield portion, in a setup as specified, at least partially covers a patient table of the magnetic resonance imaging device and/or a space occupied by a person lying on the patient table relative to a horizontal line of sight when the magnetic resonance imaging device is being used in an intended manner; and
at least one articulating portion disposed between said at least one flatly extending shield portion and said frame portion or a further portion and said at least one articulating portion is configured to enable a rotational adjustment of said at least one flatly extending shield portion or said further portion, about two mutually perpendicular articulation axes.

14. The safety device according to claim 13, wherein said at least one articulating portion has a ball joint.

15. The safety device according to claim 14, wherein said at least one articulating portion has two support rods which are each connected to said frame portion and said at least one flatly extending shield portion by means of said ball joint.

16. The safety device according to claim 13, wherein said at least one flatly extending shield portion has a membranous body with a closed surface.

17. The safety device according to claim 16, wherein said membranous body has, on at least one edge facing toward a tunnel of the magnetic resonance imaging device in the intended use state, an edge which is bent away from the tunnel.

18. The safety device according to claim 16, wherein said membranous body has a marginal recess or an internal opening formed therein which enables a hose or other conduit means to be fed into a tunnel of the magnetic resonance imaging device during intended use.

19. The safety device according to claim 13, wherein said at least one flatly extending shield portion has a ring-shaped frame on which a plurality of cables are stretched to form a quasi-closed surface.

20. The safety device according to claim 19, wherein said cables are arranged parallel to one another and in two layers in a thickness direction and offset transversely to their longitudinal extent.

21. The safety device according to claim 20, wherein said further portion is embodied as a further shield portion and is movably coupled to said at least one flatly extending shield portion by means of said at least one articulating portion or a further articulating portion.

22. The safety device according to claim 21,
wherein said at least one flatly extending shield portion is coupled to said frame portion by means of said at least one articulating portion; and
wherein said at least one flatly extending shield portion is coupled to said further shield portion by means of said further articulating portion, which has an articulation with at least one pivot axis which, in the intended use state, lies in a plane perpendicular to a tunnel axis of a tunnel of the magnetic resonance imaging device.

23. The safety device according to claim 13, further comprising a telescopic portion connected between said at least one flatly extending shield portion and said frame portion and which, in the intended use state, has a telescopic function oriented parallel to a tunnel axis of a tunnel of the magnetic resonance imaging device.
